(19) United States
(12) Patent Application Publication
(10) Pub. No.: US 2026/0362782 A1
(43) Pub. Date: Nov. 12, 2026

(54) DISLOCATION FILTERING WITH HIGHLY DOPED SILICON LAYERS FOR SOURCE/DRAIN APPLICATIONS

(71) Applicant: Applied Materials, Inc., Santa Clara, CA (US)

(72) Inventors: Nupur BHARGAVA, Santa Clara, CA (US); Pierre TOMASINI, Sunnyvale, CA (US)

(21) Appl. No.: 19/203,983

(22) Filed: May 9, 2025

(51) Int. Cl. H10D 84/01; C30B 25/18; C30B 29/06; C30B 29/08; H10P 14/20

(52) U.S. Cl. CPC H10D 84/0133; C30B 25/18; C30B 29/06; C30B 29/08; H10P 14/3411; H10P 14/3444

(57) ABSTRACT

Gate-all-around (GAA) transistor devices and methods for forming GAA transistor devices are provided. The method includes epitaxially growing a liner layer of semiconductor material on a pair of opposing sidewall surfaces and a bottom surface, the pair of opposing sidewall surfaces and the bottom surface defining a source/drain cavity. The method further includes epitaxially growing a fill layer of semiconductor material on the liner layer of semiconductor material in the source/drain cavity by a bottom-up growth process, the fill layer of semiconductor material partially filing the source/drain cavity. The method further includes epitaxially growing a doped silicon insertion layer on the fill layer of semiconductor material. The method further includes repeating epitaxially growing the fill layer and epitaxially growing the doped silicon insertion layer to achieve a targeted thickness.

### BACKGROUND

### Field

Embodiments of the present disclosure generally relate to semiconductor devices and methods for forming semiconductor devices. More specifically, embodiments of the present disclosure generally relate to gate-all-around (GAA) transistor devices and methods for forming GAA transistor devices.

### Description of the Related Art

The electronics industry is experiencing an ever-increasing demand for smaller and faster electronic devices, which are simultaneously able to support a greater number of increasingly complex and sophisticated functions. Accordingly, there is a continuing trend in the semiconductor industry to manufacture low-cost, high-performance, and low-power integrated circuits (ICs). These goals have been achieved in large part by scaling down semiconductor IC dimensions (e.g., minimum feature size) and thus improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device is the gate-all-around transistor (GAA). In a GAA device, all side surfaces of the channel region are surrounded by the gate electrode, which allows for fuller depletion in the channel region and results in less short-channel effects due to a steeper sub-threshold current swing and smaller drain induced barrier lowering (DIBL).

As transistor dimensions are scaled down to smaller technology nodes, there is a need for further improvements in GAA design and manufacturing.

### SUMMARY

In one aspect, a method of forming a semiconductor device is provided. The method includes epitaxially growing a liner layer of semiconductor material on a pair of opposing sidewall surfaces and a bottom surface, the pair of opposing sidewall surfaces and the bottom surface defining a source/drain cavity. The method further includes epitaxially growing a fill layer of semiconductor material on the liner layer of semiconductor material in the source/drain cavity by a bottom-up growth process, the fill layer of semiconductor material partially filing the source/drain cavity. The method further includes epitaxially growing a doped silicon insertion layer on the fill layer of semiconductor material. The method further includes repeating epitaxially growing the fill layer and epitaxially growing the doped silicon insertion layer to achieve a targeted thickness.

Embodiments may include one or more of the following. The doped silicon insertion layer comprises silicon doped with boron. The liner layer comprises silicon germanium doped with a p-type dopant, the liner layer having a first germanium concentration and a first dopant concentration. The fill layer comprises silicon germanium doped with the p-type dopant, the fill layer having a second germanium concentration, which is greater than the first germanium concentration and a second dopant concentration, which is greater than the first dopant concentration. Epitaxially growing the liner layer is performed at a first temperature in a range from about 700 degrees Celsius to about 750 degrees Celsius. Epitaxially growing the fill layer is performed at a second temperature in a range from about 500 degrees Celsius to about 700 degrees Celsius and the second temperature is less than the first temperature. Epitaxially growing the liner layer is performed at a first pressure in a range from about 10 Torr to about 200 Torr. Epitaxially growing the fill layer is performed at a second pressure in a range from about 5 Torr to about 20 Torr and the second pressure is less than the first pressure.

In another aspect, a method of forming a semiconductor device is provided. The method includes epitaxially growing a first liner layer of semiconductor material on a pair of opposing sidewall surfaces and a bottom surface, the pair of opposing sidewall surfaces and the bottom surface defining a source/drain cavity. The method further includes epitaxially growing a second liner layer of semiconductor material on the first liner layer of semiconductor material, the second liner layer of semiconductor material comprises doped silicon. The method further includes epitaxially growing a fill layer of semiconductor material on the second liner layer of semiconductor material in the source/drain cavity by a bottom-up growth process.

Embodiments may include one or more of the following. The second liner layer of semiconductor material comprises silicon doped with boron. The first liner layer comprises silicon germanium doped with a p-type dopant, the first liner layer having a first germanium concentration and a first dopant concentration. The fill layer comprises silicon germanium doped with the p-type dopant, the fill layer having a second germanium concentration, which is greater than the first germanium concentration and a second dopant concentration, which is greater than the first dopant concentration. Epitaxially growing the first liner layer is performed at a first temperature in a range from about 700 degrees Celsius to about 750 degrees Celsius. Epitaxially growing the fill layer is performed at a second temperature in a range from about 500 degrees Celsius to about 700 degrees Celsius and the second temperature is less than the first temperature. Epitaxially growing the first liner layer is performed at a first pressure in a range from about 10 Torr to about 200 Torr. Epitaxially growing the fill layer is performed at a second pressure in a range from about 5 Torr to about 20 Torr and the second pressure is less than the first pressure.

In yet another aspect, a method of forming a semiconductor device is provided. The method includes epitaxially growing a buffer layer of semiconductor material on a bottom surface, the bottom surface and a pair of opposing sidewall surfaces defining a source/drain cavity, the bottom surface further defining a recess formed in a silicon-containing substrate, the buffer layer filling the recess. The method further includes epitaxially growing a liner layer of semiconductor material on the pair of opposing sidewall surfaces and a top surface of the buffer layer. The method further includes epitaxially growing a fill layer of semiconductor material on the liner layer of semiconductor material in the source/drain cavity by a bottom-up growth process.

Embodiments may include one or more of the following. The buffer layer comprises silicon doped with boron. The liner layer comprises silicon germanium doped with a p-type dopant, the liner layer having a first germanium concentration and a first dopant concentration. The fill layer comprises silicon germanium doped with the p-type dopant, the fill layer having a second germanium concentration, which is greater than the first germanium concentration and a second dopant concentration, which is greater than the first dopant concentration. Epitaxially growing the liner layer is performed at a first temperature in a range from about 700 degrees Celsius to about 750 degrees Celsius. Epitaxially growing the fill layer is performed at a second temperature in a range from about 500 degrees Celsius to about 700 degrees Celsius and the second temperature is less than the first temperature. Epitaxially growing the liner layer is performed at a first pressure in a range from about 10 Torr to about 200 Torr. Epitaxially growing the fill layer is performed at a second pressure in a range from about 5 Torr to about 20 Torr and the second pressure is less than the first pressure.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates one example, of a nanostructure field-effect transistor (nano-FET) in a three dimensional view in accordance with one or more embodiments of the present disclosure.

FIG. 2 illustrates one example of a flow chart of a method of forming a nano-FET structure in accordance with one or more embodiments of the present disclosure.

FIGS. 3A-3G illustrate schematic views of various stages of forming a nano-FET structure in accordance with one or more embodiments of the present disclosure.

FIG. 4 illustrates one example of a flow chart of a method of forming a nano-FET structure in accordance with one or more embodiments of the present disclosure.

FIGS. 5A-5C illustrate schematic views of various stages of forming a nano-FET structure in accordance with one or more embodiments of the present disclosure.

FIG. 6 illustrates one example of a flow chart of a method of forming a nano-FET structure in accordance with one or more embodiments of the present disclosure.

FIGS. 7A-7D illustrate schematic views of various stages of forming a nano-FET structure in accordance with one or more embodiments of the present disclosure.

FIG. 8 illustrates a plan view of a cluster tool in accordance with one or more embodiments of the present disclosure.

FIG. 9 illustrates a cross-sectional view of a processing chamber in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to semiconductor devices and methods for forming semiconductor devices. More specifically, the present disclosure relates to GAA transistor devices and methods for forming GAA transistor devices.

Scaling down of silicon metal oxide semiconductor (MOS) devices has become a major challenge in the semiconductor industry. One problem with the scaling of conventional planar devices are the short channel effects, which start to dominate over device performance. One solution for this problem came with the introduction of multi-gate devices with three dimensional architecture, such as fin based semiconductor devices or FinFETs and GAA devices. Due to their three-dimensional architecture with either the gate being wrapped around a thin semiconductor fin for FINFET or the gate electrode surrounding all side surfaces of the channel region for GAA, improved gate control (and thus less short channel effects) over the channel could be achieved by using multiple gates.

Recess cavities typically have issues with multiple crystallographic planes at the bottom of the recess. Epitaxial films deposited in the recess grow in the multiple crystallographic planes at the bottom of the recess cause uncontrolled faceting and defects. Defects are detrimental to the properties of the device such as electron and hole mobility affecting device performance. In addition, defects propagate to the active area of the device. Thus, there is a need for improved nucleation in the inactive parts of the device to provide improved performance in the active regions of the device. Current approaches use a heteroepitaxy layer such as a SiGe or SiGeB layer. However, these heteroepitaxy layers cause lattice mismatch, which can lead to the formation of dislocation defects from the starting surface of the recess. Another current approach increases the strain in the recess and silicon channel by increasing the percentage of germanium in the SiGe/SiGeB fill. With the increase in the percentage of germanium, the recess fill is more prone to dislocations from the mismatch between the starting silicon surface and the SiGeB fill.

In one or more embodiments, a doped silicon layer is provided. The doped silicon layer (p-type or n-type depending upon the application) provides a means to initiate a defect-free interface of the active device areas in the recess. The doped silicon layer is grown completely strained with the substrate and thus does not contribute to the strain in the film either reducing or preventing defects. The doped silicon layer is used as a buffer, providing a single plane starting surface for subsequent fill. The doped silicon layer also provides a contamination free starting surface.

In one or more embodiments, a highly boron-doped silicon layer is tensile strained as opposed to the compressively strained SiGe/SiGeB. When the boron-doped silicon layer is added to the SiGe/SiGeB as insertion layers, the strain field is modified due to the change of the sign of the strain from compressive to tensile. With the boron-doped silicon insertion layer, the threading dislocation tends to bend over going from strain field to another. Alternating the strain field is a method to confine the dislocation of the bottom of the recess.

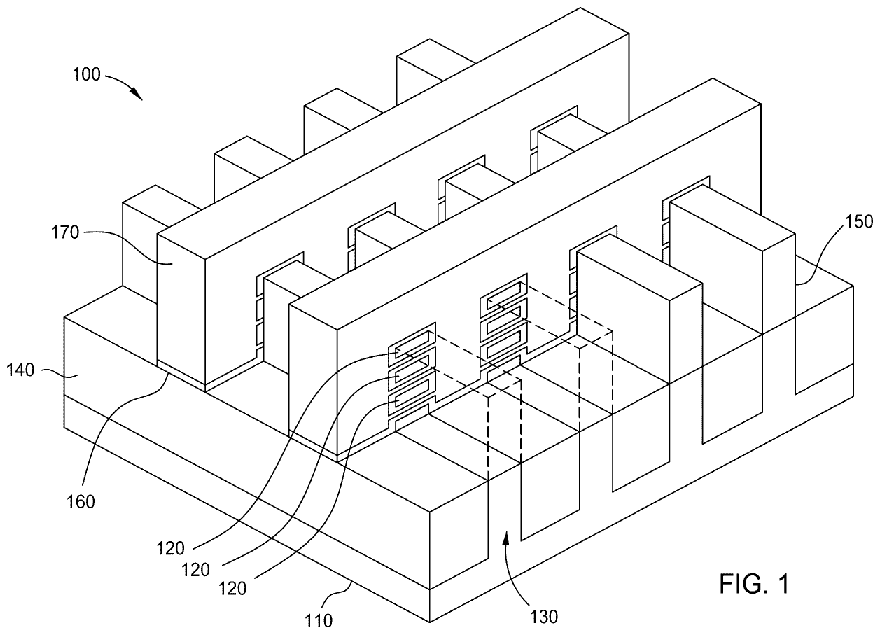

FIG. 1 illustrates one example, of a nanostructure field-effect transistor (nano-FET) 100 in a three-dimensional view in accordance with one or more embodiments of the present disclosure. The nano-FET 100 includes nanostructures 120, for example, nanosheets, nanowire, or the like, formed over fin structures 130 on a substrate 110, for example, a semiconductor substrate, wherein the nanostructures 120 act as channel regions for the nano-FET. The nanostructure 120 may include p-type nanostructures, n-type nanostructures, or a combination thereof. Isolation regions 140 are disposed between adjacent fin structures 130, which may protrude above and from between neighboring isolation regions 140. Although the isolation regions 140 are described/illustrated as being separate from the substrate 110, as used herein, the term “substrate” may refer to the semiconductor substrate alone or a combination of the semiconductor substrate and the isolation regions. Additionally, although a bottom portion of the fin structures 130 are illustrated as being single, continuous materials with the substrate 110, the bottom portion of the fin structures 130 and/or the substrate 110 may include a single material or a plurality of materials. In this context, the fin structures 130 refer to the portion extending between the neighboring isolation regions 140.

Gate dielectric layers 160 are over top surfaces of the fin structures 130 and along top surfaces, sidewalls, and bottom surfaces of the nanostructures 120. Gate electrodes 170 are over the gate dielectric layers 160. Epitaxial source/drain regions 150 are disposed on the fin structures 130 on opposing sides of the gate dielectric layers 160 and the gate electrodes 170. Source/drain region(s) may refer to a source or a drain, individually or collectively dependent upon the context.

Embodiments discussed herein are applicable to nano-FETs formed using a gate-last process and nano-FETs formed using a gate-first process. Also, some embodiments contemplate aspects used in planar devices, such as planar FETs or in fin field-effect transistors (FinFETs).

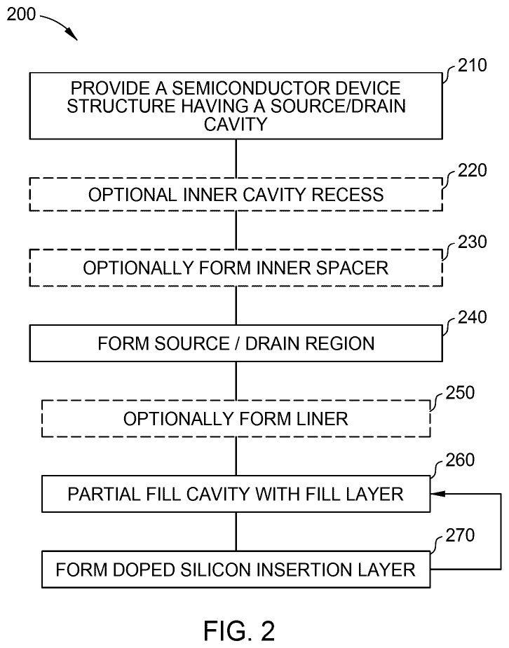

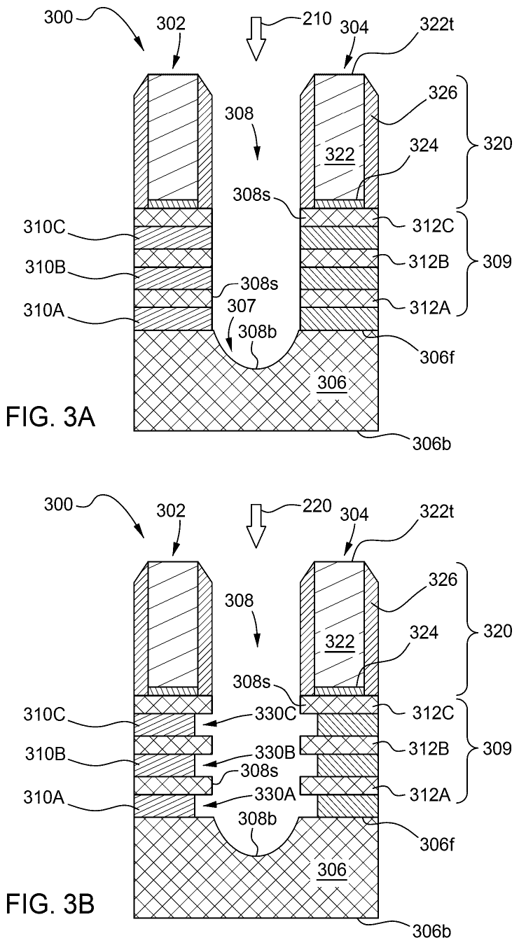

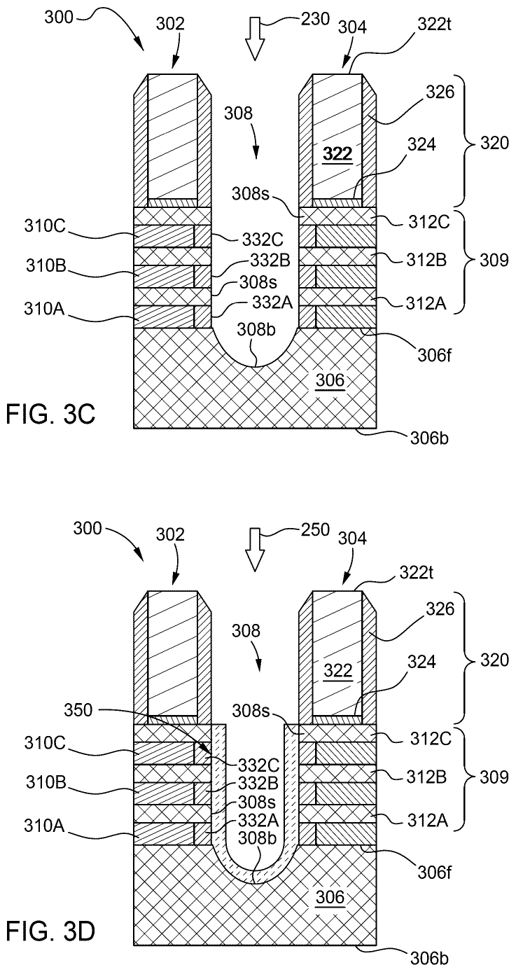

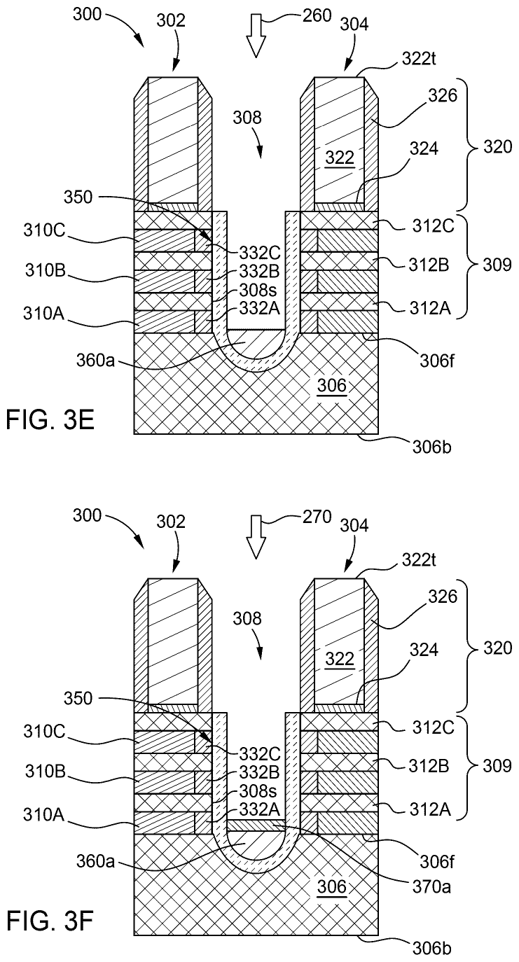

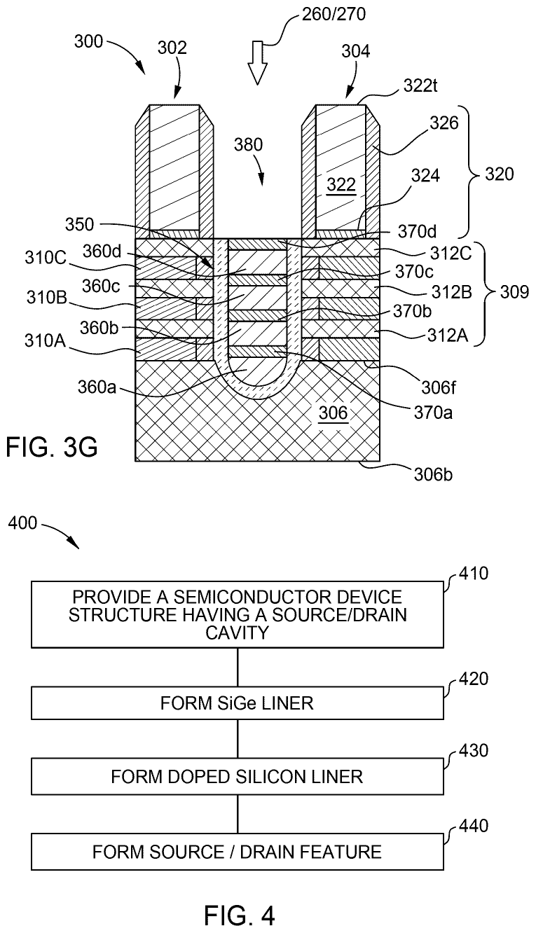

FIG. 2 illustrates an exemplary flow chart of a method 200 of forming a nano-FET structure in accordance with one or more embodiments of the present disclosure. FIGS. 3A-3G illustrate schematic views of various stages of forming a nano-FET structure in accordance with one or more embodiments of the present disclosure. With reference to FIGS. 3A-3G, schematic views of some embodiments of a nano-FET structure at various stages of manufacture are provided to illustrate the method of FIG. 2. Although FIGS. 3A-3G are described in relation to the method 200, it will be appreciated that the structures disclosed in FIGS. 3A-3G are not limited to the method 200, but instead may stand alone as structures independent of the method 200. Similarly, although the method 200 is described in relation to FIGS. 3A-3G, it will be appreciated that the method 200 is not limited to the structures disclosed in FIGS. 3A-3G, but instead may stand alone independent of the structures disclosed in FIGS. 3A-3g. The method 200 may be used to form portions of the nano-FET 100 depicted in FIG. 1.

Referring to FIG. 3A, at operation 210 a semiconductor device structure 300 having a source/drain cavity 308 is provided. The semiconductor device structure 300 may be or be part of a multi-gate device with three-dimensional architecture, such as fin based semiconductor devices including nano-FETs and gate-all-around (GAA) transistor devices. The semiconductor device structure 300 includes a first semiconductor region 302 also referred to as a first fin structure and a second semiconductor region 304 also referred to as a second fin structure formed on a substrate 306. The first semiconductor region 302 and the second semiconductor region 304 are separated by a feature, such as the source/drain cavity 308, which exposes the substrate 306. In one or more embodiments, as is shown in FIG. 3A, a portion of the source/drain cavity 308 extends into the substrate 306.

As shown in FIG. 3A, the first semiconductor region 302 and the second semiconductor region 304 each include a plurality of alternating semiconductor layers 309. The plurality of alternating semiconductor layers 309 include first semiconductor layers 310A-C and second semiconductor layers 312A-C that are alternately and repeatedly stacked on the substrate 306. Although the example shown in FIG. 3A shows three pairs, each pair including the first semiconductor layer 310A-C and the second semiconductor layer 312A-C, the number of pairs may be varied based on different process needs with or without the first semiconductor layers 310A-C and the second semiconductor layers 312A-C being needed. The first semiconductor layers 310A-C are formed of a first material having etch selectivity to a second material of which the second semiconductor layers 312A-C are formed, for example, an etch rate of the first material is higher than an etch rate of the second material. The etch selectivity, a ratio of the etch rate of the first material to the etch rate of the second material, is between about 10:1 to 200:1. Example combinations of the first material and the second material include silicon—germanium (SiGe)/silicon (Si), silicon—germanium (SiGe)/germanium (Ge), and germanium tin (GeSn)/silicon (Si). In one or more embodiments, which can be combined with other embodiments, the first semiconductor layers 310A-C are or include SiGe and the second semiconductor layers 312A-C are or include silicon, for example, crystalline silicon. The second semiconductor layers 312A-C may serve as channels having a width of between several nanometers and several tens of nanometers. The first semiconductor layers 310A-C and the second semiconductor layers 312A-C can be nanostructures, for example, nanowires or nanosheets.

The first semiconductor layers 310A-C and the second semiconductor layers 312A-C may be formed using any suitable deposition technique, such as chemical vapor deposition (CVD), atomic layer deposition (ALD), or physical vapor deposition (PVD), and the source/drain cavity 308 is formed by a patterning technique, such as lithography followed by an etch or ashing process. The first semiconductor layers 310A-C and the second semiconductor layers 312A-C may each have thickness of between about 1 nm and about 15 nm, for example, about 10 nm. The selective etching of the first semiconductor layers 310A-C may be performed by any appropriate etch process, such as a dry plasma etch process.

The semiconductor device structure 300 further includes a dummy gate structure 320 formed over at least a portion of each of the first semiconductor region 302 and the second semiconductor region 304. The dummy gate structure 320 includes a dummy gate 322. The dummy gate 322 may be a conductive or nonconductive material and may be selected from amorphous silicon, doped or undoped polycrystalline silicon (polysilicon), polycrystalline silicon—germanium (poly-SiGe), silicon oxide, metallic nitrides, metallic silicides, metallic oxides, and metals. The dummy gate 322 may be formed using any suitable techniques such as physical vapor deposition (PVD), plasma enhanced chemical vapor deposition (PECVD), CVD, ALD, or the like. The dummy gate 322 includes a top surface 322t, which defines a top surface of the semiconductor device structure 300.

The dummy gate structure 320 may further includes a dummy gate dielectric layer 324 formed on or over the alternating semiconductor layers 309, for example, on or over the first semiconductor layer 310C. The dummy gate 322 is formed on or over the dummy gate dielectric layer 324 with the dummy gate dielectric layer 324 formed in between the alternating semiconductor layers 309 and the dummy gate 322 such that the dummy gate dielectric layer 324 separates the dummy gate 322 from the alternating semiconductor layers 309. The dummy gate dielectric layer 324 protects the underlying alternating semiconductor layers 309 during subsequent removal of the dummy gate 322. The dummy gate dielectric layer 324 may be formed of any suitable oxide, for example, silicon oxycarbonitride, silicon oxide, silicon oxynitride, or the like, using any suitable techniques such as thermal oxidation, or deposited by PECVD, CVD, ALD, or the like.

The dummy gate structure 320 may further include one or more spacers 326. The spacer 326 may function as a spacer for forming self-aligned source/drain regions. The spacer 326 may be formed along the sidewalls of the dummy gate 322 and the dummy gate dielectric layer 324. The spacer 326 may be formed of silicon oxycarbonitride, silicon oxide, silicon nitride, silicon oxynitride, or the like, using any suitable techniques such as thermal oxidation, or deposited by PECVD, CVD, ALD, or the like.

The dummy gate structure 320 may further include a capping layer (not shown). The capping layer may be or include a dielectric material. The capping layer can be formed from the same material as the spacer. The capping layer can be formed from a material that is different from the material of the spacer.

The substrate 306 has a frontside 306f (also referred to as a front surface) and a backside 306b opposite the frontside 306f. The substrate 306 may be a material such as crystalline silicon (e.g., Si<100> or Si<111>), silicon oxide, strained silicon, silicon—germanium, germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, or sapphire. In one or more embodiments, which can be combined with other embodiments, the substrate 306 is or includes crystalline silicon. In one or more embodiments, the substrate 306 includes a recess 307, which extends from the frontside 306f into the substrate 306.

The source/drain cavity 308 is defined by a pair of opposing sidewall surfaces 308s and a bottom surface 308b. The sidewall surfaces 308s may be defined by the dummy gate structure 320 and the alternating pairs of the first semiconductor layers 310A-C and the second semiconductor layers 312A-C. The bottom surface 308b of the source/drain cavity 308 is defined by the recess 307 formed in the substrate 306. In one or more embodiments, which can be combined with other embodiments, the bottom surface 308b has a first crystal plane orientation, for example, (100) and the sidewall surfaces 308s have a second crystal plane orientation, for example, (110).

Referring to FIG. 3B, at operation 220, an inner cavity recess process may be performed. As shown in FIG. 3B, portions of the sidewall surfaces 308s of the plurality of alternating semiconductor layers 309 formed of the first semiconductor layers 310A-C exposed by the source/drain cavity 308 are etched to form sidewall recesses 330A-C along the sidewall surfaces 308s. Although sidewalls of the first semiconductor layers 310A-C in the sidewall recesses 330A-C are illustrated as being straight in FIG. 3B, the sidewalls may be concave or convex. The sidewalls may be etched using isotropic etching processes, such as wet etching or the like. In one or more embodiments in which the first semiconductor layers 310A-C include, for example, SiGe, and the second semiconductor layers 312A-C include, for example, Si or SiC, a wet etch process with tetramethylammonium hydroxide (TMAH), ammonium hydroxide (NH₄OH), or the like may be used to etch the sidewalls of the first semiconductor layers 310A-C.

Referring to FIG. 3C, at operation 230, inner spacer layers are formed. As shown in FIG. 3C, first inner spacers 332A-C are formed in the sidewall recess 330A-C. The first inner spacers 332A-C may be formed by depositing an inner spacer layer (not separately illustrated) over the structure illustrated in FIG. 3B. The first inner spacers 332A-C act as isolation features between subsequently formed source/drain regions and a gate structure. As will be discussed in greater detail below, source/drain regions will be formed in the source/drain cavity 308, while the first semiconductor layers 310A-C in the n-type region and in the p-type region (not shown) will be replaced with corresponding gate structures.

The inner spacer layer may be deposited by a conformal deposition process, such as CVD, ALD, or the like. The inner spacer layer may be or include a material such as silicon nitride, silicon oxynitride, or silicon oxycarbonitride, although any suitable material, such as low-dielectric constant (low-k) materials having a k-value less than about 3.5, may be utilized. The inner spacer layer may then be anisotropically etched to form the first inner spacers 332A-C. Although outer sidewalls of the first inner spacers 332A-C are illustrated as being flush with sidewalls of the second semiconductor layers 312A-C in the n-type region shown in FIG. 3C and in the p-type region (not shown), the outer sidewalls of the first inner spacers 332A-C may extend beyond or be recessed from sidewalls of the second semiconductor layers 312A-C and/or the first inner spacers 332A-C, respectively.

Moreover, although the outer sidewalls of the first inner spacers 332A-C are illustrated as being straight in FIG. 3C, the outer sidewalls of the first inner spacers 332A-C may be concave or convex. The inner spacer layer may be etched by an anisotropic etching process, such as reactive ion etching (RIE) or the like. The first inner spacers 332A-C may be used to prevent damage to the subsequently formed source/drain region, for example, the source/drain feature 380 discussed below with respect to FIG. 3J, by subsequent etching processes, such as etching processes used to form gate structures.

The first inner spacers 332A-C may be formed of dielectric material, such as silicon nitride (Si₃N₄), silicon oxynitride (SiON), silicon oxycarbide (SiOC), or silicon oxycarbonitride (SiOCN). In one or more embodiments, the first inner spacers 332A-C are formed from the same material as the spacer 326. For example, both the first inner spacers 332A-C and the spacer 326 are formed from silicon oxycarbonitride. In one or more other embodiments, the first inner spacers 332A-C are formed from a material that is different from the material of the spacer 326.

It should be understood that although the first inner spacers 332A-C are shown, in some embodiments, the first inner spacers 332A-C are not present. For example, operation 220 and operation 230 are omitted and the method 200 begins with operation 240.

A cleaning process may be performed to remove contaminants, such as native oxide layers, patterning residue, and debris present on exposed surfaces of the source/drain cavity 308. The cleaning process can include a dry clean, a wet clean, or a combination thereof.

The cleaning process may include use of standard clean 1 (RCA SC-1, a mixture of deionized (DI) water, ammonium hydroxide, and hydrogen peroxide), standard clean 2 (RCA SC-2, a mixture of DI water, hydrochloric acid and hydrogen peroxide), SPM (a sulfuric peroxide mixture), and/or DHF wet cleaning using dilute hydrofluoric acid solution for oxide removal. The dry cleaning process may include an anisotropic remote plasma assisted dry etch process, such as a reactive ion etching (RIE) process, using a plasma formed from a gas including argon (Ar), helium (He), or a combination thereof. The dry cleaning process may include an isotropic plasma etching process, such as a SiCoNi™ dry chemical etching process, using a plasma formed from a gas including ammonia (NH₃), nitrogen trifluoride (NF₃), hydrogen fluoride (HF), or a combination thereof, and a carrier gas, such as nitrogen (N₂), hydrogen (H₂), or a combination thereof. The dry chemical etching process is selective for oxide layers, and thus does not readily etch silicon, germanium, or nitride layers regardless of whether the layers are amorphous, crystalline, or polycrystalline. The dry cleaning process may include an inductively coupled plasma (ICP) etching process, using a plasma formed from a gas including chlorine (Cl₂) and hydrogen (H₂), and a carrier gas including argon (Ar) and helium (He). The dry clean process may include helium (He) and hydrogen (H2) treatment. In one or more embodiments, the cleaning process includes exposing the semiconductor device structure 300 to atomic hydrogen radicals. In one or more embodiments, the cleaning process includes exposing the semiconductor device structure 300 to a thermal annealing process at a temperature of 600 degrees Celsius or higher, for example, in a range from about 650 degrees Celsius to about 900 degrees Celsius. The cleaning process can remove surface oxide, carbon, and debris in order to ensure a clean semiconductor surface, which facilitates growth of high quality epitaxial layers.

Referring to FIGS. 3D-3G, at operation 240, the source/drain feature 380 is formed. The composition of the source/drain feature depends on the conductivity type of the semiconductor device structure 300. If the semiconductor device structure 300 is an n-type structure, the source/drain features 380 can include silicon (Si) doped with an n-type dopant such as phosphorous or arsenic. If the semiconductor device structure 300 is a p-type structure, the source/drain features 380 can include silicon germanium (SiGe) doped with a p-type dopant, such as boron or gallium. In some embodiments, as is shown in FIGS. 3D-3G, the source/drain feature 380 includes multiple epitaxial layers each formed by an epitaxial process. The source/drain feature 380 may be epitaxially and selectively formed from the exposed sidewall surfaces 308s of the first semiconductor layers 310A-C, the second semiconductor layers 312A-C and the bottom surface 308b, which is defined by the substrate 306. Suitable epitaxial processes include vapor-phase epitaxial (VPE), ultra-high vacuum CVD (UHV-CVD), molecular beam epitaxy (MBE), low pressure CVD (LPCVD), plasma epitaxy, and/or other suitable processes. The epitaxial growth process may use gaseous precursors, which interact with the material of the substrate 306 and the materials of the first semiconductor layers 310A-C and the second semiconductor layers 312A-C.

Referring to FIG. 3D, optionally at operation 250, a liner layer of semiconductor material 350 is formed. The liner layer of semiconductor material 350 is epitaxially grown on the exposed silicon-containing surfaces, for example, the sidewalls of the first semiconductor layers 310A-C and the second semiconductor layers 312A-C and the bottom surface 308b of the recess, which is defined by the substrate 306. The liner layer of semiconductor material 350 can be a conformal layer. The composition of the liner layer of semiconductor material 350 can depend on the conductivity type of the semiconductor device structure 300. If the semiconductor device structure 300 is an n-type structure, the liner layer of semiconductor material 350 can include silicon (Si) doped with an n-type dopant such as phosphorous or arsenic. If the semiconductor device structure 300 is a p-type structure, the liner layer of semiconductor material 350 can include silicon germanium (SiGe) doped with a p-type dopant, such as boron or gallium. Suitable epitaxial processes include vapor-phase epitaxial (VPE), ultra-high vacuum CVD (UHV-CVD), molecular beam epitaxy (MBE), low pressure CVD (LPCVD), reduced pressure CVD (RPCVD), plasma epitaxy, and/or other suitable processes. The epitaxial growth process may use gaseous precursors, which interact with the material of the substrate 306 and the second semiconductor layers 312A-C.

The liner layer of semiconductor material 350 can function as a template layer enabling bottom-up growth of the fill layer of semiconductor material 360. The liner layer of semiconductor material 350 is formed along surfaces of the source/drain cavity 308, for example the sidewall surfaces 308s and the bottom surface 308b of the source/drain cavity 308.

A thickness of the liner layer of semiconductor material 350 can be equal to or greater than 50 angstroms (Å). In one or more embodiments, as is shown in FIG. 3D, the thickness of the liner layer of semiconductor material 350 is conformal along the sidewall surfaces 308s and the bottom surface 308b.

In one or more embodiments, a material of the liner layer of semiconductor material 350 is silicon germanium (Si₁₋ₓGeₓ, where x is in a range from about 10 to about 30 or in a range from about 10 to about 20). The liner layer of semiconductor material 350 can be epitaxially grown using a germanium source precursor and a silicon source precursor. The germanium source precursor can be or include germane (GeH₄), a higher order germane, a halogenated germane, an organogermane, or combinations thereof. Higher order germanes include compounds with an empirical formula GeₓH₍₂ₓ₊₂₎, such as digermane (Ge₂H₆), trigermane (Ge₃H₈), and tetragermane (Ge₄H₁₀). Organogermanes include compounds with an empirical formula R_{y}GeₓH_{(2x+2-y)}, where R=methyl, ethyl, propyl or butyl, such as methylgermane ((CH₃)GeH₃), dimethylgermane ((CH₃)₂GeH₂), ethylgermane ((CH₃CH₂)GeH₃), methyldigermane ((CH₃)Ge₂H₅), dimethyldigermane ((CH₃)₂Ge₂H₄) and hexamethyldigermane ((CH₃)₆Ge₂). Halogenated germanes include chlorinated germanes. The chlorinated germane gases include germanium tetrachloride (GeCl₄), dichlorogermane (GeH₂Cl₂), trichlorogermane (GeHCl₃), hexachloro-digermane (Ge₂Cl₆), or a combination thereof. The silicon source precursor can be or include silane (SiH₄), a higher order silane, halogenated silane, organosilane, or a combination thereof. Higher order silanes include compounds with an empirical formula SiₓH₍₂ₓ₊₂₎, such as disilane (Si₂H₆), trisilane (Si₃H₈), and tetrasilane (Si₄H₁₀). Halogenated silanes include compounds with the empirical formula X′_{y}SiₓH_{(2x+2-y}), where X′=F, Cl, Br or I, such as dichlorosilane (SiH₂Cl₂), tetrachlorosilane (SiCl₄), and hexachlorodisilane (Si₂Cl₆), and trichlorosilane (SiHCl₃). Organosilanes include compounds with an empirical formula R_{y}SiₓH_{(2x+2-y)}, where R=methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄) and hexamethyldisilane ((CH₃)₆Si₂).

In one or more embodiments, the silicon source precursor is silane, the etchant source gas is HCl, and the germanium source precursor is GeH4. In one or more other embodiments, the silicon source precursor is dichlorosilane and the germanium source precursor is germane.

A flow rate of the germanium source precursor can be in a range from about 10 standard cubic centimeters per minute (sccm) to about 200 sccm, and a flow rate of the silicon source precursor can be in a range from about 10 sccm to about 1000 sccm. A ratio of the flow rate of the germanium source precursor to the flow rate of the silicon source precursor can be in a range from about 1:5 to about 1.5:1. A first pressure of an environment in a processing chamber in which the epitaxial growth is performed can be maintained in a range from about 3 Torr to about to about 200 Torr, or from about 50 Torr to about 200 Torr, or from about 5 Torr to about 60 Torr, or from about 5 Torr to about 20 Torr. A first temperature of the substrate 306 during the epitaxial growth can be maintained at about 350 °C or above, or at about 380 °C or above, or at about 400 °C or above, or at about 500 °C or above, or at about 590 °C or above, such as about 600 °C or above, and more particularly in a range from about 350 °C to about 900 °C, or from about 350 °C to about 400 °C, or from about 600 °C to about 750 °C.

An etchant can be flowed in the epitaxial growth process of operation 250 to selectively etch epitaxially grown material, such as grown on an amorphous surface, for example, a dielectric surface such as an inner spacer. An etchant can be or include HCl, HF, HBr, Br₂, Si₂Cl₆, SiCl₄, SiHCl₃, SiH₂Cl₂, CCl₄, Cl₂, GeCl₄, GeHCl₃, or a combination thereof. A flow rate of an etchant gas can be in a range from about 0 sccm to about 100 sccm. A carrier gas, for example, an inert gas, such as nitrogen (N₂), argon (Ar), the like, or a combination thereof, can be used in combination with the germanium source precursor, silicon source precursor, etchant, and/or a combination thereof.

In one or more embodiments, the liner layer of semiconductor material 350 can be doped, such as boron-doped silicon germanium (Si₁₋ₓGeₓ(B) or more generally, SiGe(B)). A first concentration of a dopant in the liner layer of semiconductor material 350 can be in a range from about 1×10¹⁹ cm⁻³ to about 5×10²¹ cm⁻³. In one or more embodiments, a dopant source can be flowed during the epitaxial growth of the liner layer of semiconductor material 350 to in-situ dope the liner layer of semiconductor material 350. The dopant source can be or include a borane, organoborane (e.g., alkylboranes), and boron halide. Boranes include borane (BH₃), diborane (B₂H₆), triborane (B₃H₅), tetraborane (B₄H₁₀), pentaborane(9) (B₅H₉), pentaborane(11), hexaborane(10) (B₆H₁₀), hexaborane(12) (B₆H₁₂), and decaborane(14) (B₁₀H₁₄), while alkylboranes include compounds with an empirical formula RₓBH₍₃₋ₓ₎, where R =methyl, ethyl, propyl or butyl and x=0, 1, 2 or 3. Alkylboranes include trimethylborane ((CH₃)₃B), dimethylborane ((CH₃)₂BH), triethylborane ((CH₃CH₂)₃B), and diethylborane ((CH₃CH₂)₂BH). Boron halides include electron deficient boron halides such as boron trifluoride (BF₃), boron trichloride (BCl₃), and boron tribromide (BBr₃). A flow rate of the dopant source can be in a range from about 1 sccm to about 30 sccm. Other dopants, such as arsenide and phosphorus, may be implemented in other examples, and hence, different dopant sources can be used. In one or more embodiments, the liner layer of semiconductor material 350 can be doped by diffusion of boron or other dopants from subsequently deposited layers into the liner layer of semiconductor material 350.

The epitaxial growth of the liner layer of semiconductor material 350 can cause surfaces of the liner layer of semiconductor material 350 to replicate surfaces of the source/drain cavity 308 on which the liner layer of semiconductor material 350 is grown. Accordingly, the liner layer of semiconductor material 350 can have an upper surface that replicates the sidewall surfaces 308s of the source/drain cavity. In one or more embodiments, where the bottom surface 308b is a (100) Si surface, the bottom surface of the liner layer of semiconductor material 350 can be a (100) SiGe surface.

Referring to FIG. 3E, at operation 260, the source drain/cavity is partially filed with a fill layer of semiconductor material 360a-d (collectively 360). In one or more embodiments, the fill layer of semiconductor material 360a is grown on the underlying liner layer of semiconductor material 350. In one or more embodiments where the liner layer of semiconductor material 350 is not present, the fill layer of semiconductor material 360a is epitaxially grown on the exposed silicon-containing surfaces, for example, the sidewall surfaces 308s and the bottom surface 308b, which is defined by the substrate 306.

The fill layer of semiconductor material 360a partially fills the source/drain cavity 308 and is followed by deposition of a doped silicon insertion layer 370 at operation 270. Operation 260 and operation 270 can be repeated to fill the source/drain cavity 308 and complete the source/drain feature 380. In some embodiments, the process conditions for the epitaxial growth process of operation 260 are selected so that the fill layer of semiconductor material 360 has an increased growth rate on the (100) surfaces relative to the (110) surfaces such that the epitaxial growth process of operation 260 is a substantially bottom-up or anisotropic growth process.

In one or more embodiments, a material of the fill layer of semiconductor material 360 is silicon germanium (Si_{1-y}Ge_{y}, where y is in a range from about 30 to about 50 or in a range from about 40 to about 50), which may be doped, such as by boron (e.g., boron-doped silicon germanium (SiGe(B))). A second concentration of a dopant in the fill layer of semiconductor material 360 can be in a range from about 1×10¹⁸ cm⁻³ to about 5×10²¹ cm⁻³. In one or more embodiments, the second concentration of dopant in the fill layer of semiconductor material 360 is greater than the first concentration of dopant in the liner layer of semiconductor material 350. The fill layer of semiconductor material 360 can be epitaxially grown using a germanium source precursor and a silicon source precursor. The germanium source precursor can be or include germane (GeH₄), a higher order germane, a halogenated germane, an organogermane, or combinations thereof as previously described herein. The silicon source precursor can be or include silane (SiH₄), a higher order silane, halogenated silane, for example, dichlorosilane, organosilane, or a combination thereof as previously described herein.

In one or more embodiments for forming the fill layer of semiconductor material 360, the silicon source precursor is or includes silane, the etchant source gas is or includes HCl, and the germanium source precursor is or includes GeCl4. In one or more other embodiments for forming the fill layer of semiconductor material 360, the silicon source precursor is or includes dichlorosilane, the etchant source gas is or includes HCl, and the germanium source precursor is or includes germane.

A dopant source gas can be flowed during the epitaxial growth of the fill layer of semiconductor material 360 to in-situ doped the fill layer of semiconductor material 360. The dopant source gas can be or include a borane, organoborane (e.g., alkylboranes), and boron halide as previously described. The dopant source gas can be diborane, BCl3, or both diborane and BCl3.

An etchant can be flowed in the epitaxial growth process of operation 260 to selectively etch epitaxially grown material, such as grown on an amorphous surface, for example, a dielectric surface such as an inner spacer. An etchant gas can be or include HCl, HF, HBr, Br₂, Si₂Cl₆, SiCl₄, SiHCl₃, SiH₂Cl₂, CCl₄, Cl₂, GeCl₄, GeHCl₃, or a combination thereof. A flow rate of an etchant gas can be in a range from about 0 sccm to about 100 sccm. A carrier gas, for example, an inert gas, such as nitrogen (N₂), argon (Ar), the like, or a combination thereof, can be used in combination with the germanium source precursor, silicon source precursor, etchant, and/or a combination thereof.

A flow rate of the germanium source precursor can be in a range from about 5 sccm to about 1,000 sccm or in a range from about 50 sccm to about 500 sccm, and a flow rate of the silicon source precursor can be in a range from about 10 sccm to about 1,000 sccm or in a range from about 50 sccm to about 500 sccm. A ratio of the flow rate of the silicon source precursor to the flow rate of the germanium source precursor can be in a range from about 2:1 to about 1.5:1. A flow rate of the dopant source gas can be in a range from in a range from about 1 sccm to about 150 sccm or in a range from about 5 sccm to about 30 sccm. A carrier gas (e.g., an inert gas), such as nitrogen (N₂), argon (Ar), the like, or a combination thereof, can be used in combination with the germanium source precursor, the silicon source precursor, dopant source gas, or a combination thereof. A second pressure of an environment in a processing chamber in which the epitaxial growth is performed can be maintained in a range from about 5 Torr to about 100 Torr, or in a range from about 5 Torr to about 40 Torr, or in a range from about 5 Torr to about 20 Torr. A second temperature of the substrate 306 during the epitaxial growth can be maintained at about 350 °C or above, at about 500 °C or above, such as in a range from about 500 °C to about 700 °C, or in a range from about 540 °C to about 600 °C.

Under these conditions, epitaxial growth of the silicon germanium can be anisotropically deposited. In some examples, where the upper surface of the liner layer of semiconductor material 350 is a (100) SiGe surface, the fill layer of semiconductor material 360 can be anisotropically grown from the respective (100) SiGe surfaces in a <100> direction without substantial lateral growth in a <010> direction, such that a (110) surface is not formed. Thus, a lateral growth component of the fill layer of semiconductor material 360 can be suppressed. Suppression of a lateral growth component can reduce or eliminate a facet (e.g., a (110) surface) formed in the source/drain feature 380. During the epitaxial growth process of the source/drain feature 380, chlorine dissociated from the chlorinated germane gas can etch lateral growth that can form a (110) surface. The combination of vertical deposition and etch rates and lateral deposition and etch rates result in a vertical growth rate that is significantly greater than a lateral growth rate, which helps generate a S/D stress that will transfer into the channel region.

In one or more embodiments, the fill layer of semiconductor material 360 is epitaxially grown via a cyclic deposition/purge process including an epitaxial deposition portion followed by a purge portion. The number of cycles can be as low as one, for example, deposition/etch/deposition only. The epitaxial deposition portion includes co-flowing the silicon precursor, the germanium precursor, optionally the etchant gas, and optionally a carrier gas for a first period of time to epitaxially grow a first portion of the fill layer of semiconductor material 360 via bottom-up growth followed by the purge portion for a second period of time. The pump/purge process can be performed for any number of cycles until the source/drain feature 380 achieves a targeted thickness. In addition, the first period of time and the second period of time may be adjusted for each subsequent deposition cycle as the size of the source/drain cavity 308 decreases. In one or more embodiments, the first time period is in a range from about 5 seconds to about 120 seconds and the second time period is in a range from about 5 second to about 45 seconds. For example, during deposition of the first portion the first time period is about 30 seconds and the second time period is about 10 seconds and during deposition of a second portion, the first time period is about 10 seconds and the second time period is about 30 seconds. During the purge portion, the flow of the silicon precursor and the germanium are stopped while the flow of the etchant gas and/or carrier gas continues. Not to be bound by theory but it is believed that the purge portion removes the deposition gases from the source/drain cavity 308, which reduces or prevents deposition of the fill layer of semiconductor material 360 along the sidewall surface(s) 308s and contributes to bottom-up growth.

In one or more embodiments of the cyclic deposition/purge process, the epitaxial deposition portion includes co-flowing DCS, GeH4, and HCl and the purge portion includes stopping the flow of DCS and GeH4 while continuing to flow HCl. In one or more other embodiments, the epitaxial deposition portion includes co-flowing DCS, GeH4 and GeCl4 and the purge portion includes stopping the flow of DCS and GeH4 while continuing to flow GeCl4.

During operation 260, a second pressure of an environment in a processing chamber in which the epitaxial growth is performed can be maintained in a range from about 5 Torr to about to about 200 Torr, or from about 5 Torr to about 60 Torr, or from about 5 Torr to about 20 Torr. A second temperature of the substrate 306 during the epitaxial growth can be maintained at about 350 °C or above, or at about 380 °C or above, or at about 590 °C or above, such as about 600 °C or above, and more particularly in a range from about 350 °C to about 900 °C, or from about 350 °C to about 400 °C, or from about 700 °C to about 750 °C. The second pressure and second temperature of operation 260 may be the same as or similar to the first pressure and the first temperature of operation 250. The second pressure and second temperature of operation 260 may be different from the first pressure and the first temperature of operation 250.

Referring to FIG. 3F, at operation 270, a doped silicon insertion layer 370a-d (collectively 370) is formed on the fill layer of semiconductor material 360. The doped silicon insertion layer 370 can be a boron doped silicon layer. The doped silicon insertion layer 370 is tensile strained as opposed to the fill layer of semiconductor material 360, which is compressively strained. When the doped silicon insertion layer 370 is added to the source/drain feature 380, the strain field is modified due the change of the sign of the strain from compressive to tensile. Not to be bound by theory but it is believed that with incorporation of the doped silicon insertion layers 370, threading dislocations tend to bend over going from one strain field to another. Alternating the strain field confines the dislocation to the bottom of the recess, which limits defects in the source/drain feature 380. The number of doped silicon insertion layers 370 incorporated in the source/drain feature 380 and thickness of the insertion layers is dependent upon the severity of the dislocation nucleation. The severity of the nucleation dislocation is determined by the percent of germanium in the recess fill and the depth of the recess to be filled.

In one or more embodiments, the doped silicon insertion layer 370 is grown on the underlying fill layer of semiconductor material 360 as shown in FIG. 3F. In one or more embodiments, a material of the fill layer of semiconductor material 360 is silicon which is doped, such as by boron (e.g., boron-doped silicon (Si(B)). A third concentration of a dopant in the doped silicon insertion layer 370 can be in a range from about 1×10¹⁹ cm⁻³ to about 1×10²¹ cm⁻³. In one or more embodiments, the third concentration of dopant in the doped silicon insertion layer 370 is greater than the second concentration of dopant in the fill layer of semiconductor material 360. The doped silicon insertion layer 370 can be epitaxially grown using a silicon source precursor and dopant precursor, for example, a boron dopant precursor. The silicon source precursor can be or include silane (SiH₄), a higher order silane, halogenated silane, for example, dichlorosilane, organosilane, or a combination thereof as described herein. A dopant source can be flowed during the epitaxial growth the doped silicon insertion layer 370 to in-situ dope the doped silicon insertion layer 370. The dopant source can be or include a borane, organoborane (e.g., alkylboranes), a boron halide, or combinations thereof.

An etchant can be flowed in the epitaxial growth process of operation 270 to selectively etch epitaxially grown material, such as grown on an amorphous surface, for example, a dielectric surface such as an inner spacer. An etchant gas can be or include HCl, HF, HBr, Br₂, Si₂Cl₆, SiCl₄, SiHCl₃, SiH₂Cl₂, CCl₄, Cl₂, or a combination thereof. A flow rate of an etchant gas can be in a range from about 0 sccm to about 100 sccm. A carrier gas, for example, an inert gas, such as nitrogen (N₂), argon (Ar), the like, or a combination thereof, can be used in combination with the silicon source precursor, the dopant source, the etchant, and/or a combination thereof.

In one or more embodiments for forming the doped silicon insertion layer 370, the silicon source precursor includes or is silane, the etchant gas includes or is HCl, and the dopant source includes or is diborane and optionally BCl3. In one or more other embodiments for forming the doped silicon insertion layer 370, the silicon source precursor includes or is dichlorosilane, the etchant gas includes or is HCl, and the dopant source includes or is diborane and optionally BCl3.

A flow rate of the silicon source precursor can be in a range from about 10 sccm to about 1,000 sccm or in a range from about 50 sccm to about 500 sccm. A flow rate of the dopant source gas can be in a range from about 1 sccm to about 150 sccm or in a range from about 5 sccm to about 30 sccm. A flow rate of the etchant gas can be in a range from about 10 sccm to about 1,000 sccm or in a range from about 50 sccm to about 500 sccm. A carrier gas (e.g., an inert gas), such as nitrogen (N₂), argon (Ar), the like, or a combination thereof, can be used in combination with the germanium source precursor, the silicon source precursor, dopant source gas, or a combination thereof. A third pressure of an environment in a processing chamber in which the epitaxial growth is performed can be maintained in a range from about 5 Torr to about 100 Torr, or in a range from about 5 Torr to about 40 Torr, or in a range from about 5 Torr to about 20 Torr. A third temperature of the substrate 306 during the epitaxial growth can be maintained at about 350 °C or above, at about 500 °C or above, such as in a range from about 500 °C to about 750 °C, or in a range from about 540 °C to about 600 °C.

Operation 260 and 270 can be repeated any number of times until the source/drain feature 380 achieves a targeted thickness. In one example, operation 260 and 270 are repeated four times to achieve a targeted thickness of the source/drain feature 380 as shown in FIG. 3E.

In one or more embodiments, a purge process is performed between operations 260 and 270. During the purge process, a purge gas, which can be argon (Ar), is introduced in the processing chamber. In some embodiments, the purge gas includes hydrogen (H₂) gas. The purge process can include flowing an etchant gas as described, for example, HCl or Cl2, between operations 260 and 270. The purge process can include stopping the flow of deposition gases from operation 260 prior to commencing the flow of deposition gases for operation 270. During the purge process, processing conditions, for example, temperature and/or pressure may be adjusted.

After deposition of the source/drain features 380, an anneal process may be performed to activate the source/drain features 380. In some embodiments, the anneal process may include a rapid thermal anneal (RTA) process, a laser spike anneal process, a flash anneal process, or a furnace anneal process. The anneal process may include a peak anneal temperature in a range from about 900 degrees Celsius and about 1000 degrees Celsius. In these embodiments, the peak anneal temperature may be maintained for a duration measured by seconds or microseconds. Through the anneal process, a targeted electronic contribution of the p-type dopant in the semiconductor host, such as silicon germanium (SiGe) or germanium (Ge), may be obtained. The anneal process may generate vacancies that facilitate movement of the p-type dopant from interstitial sites to substitutional lattice sites and reduce damage or defects in the lattice of the semiconductor host.

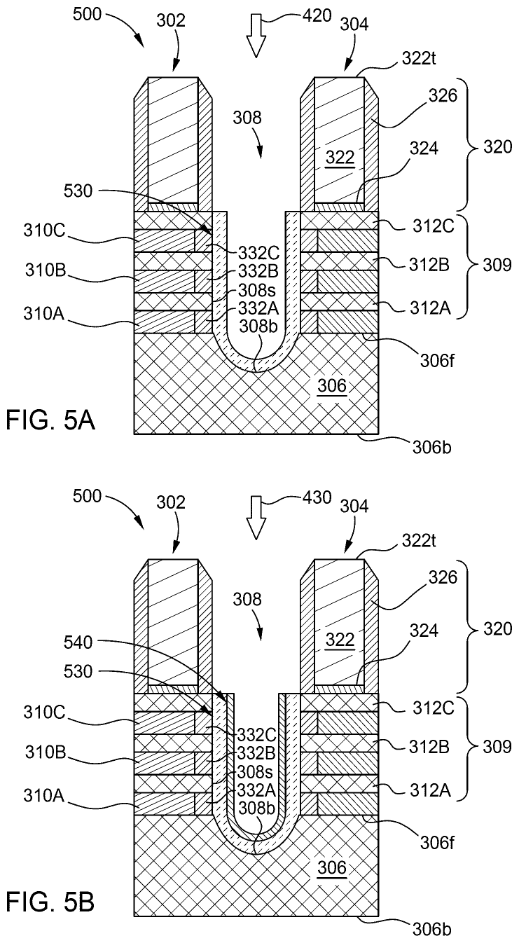

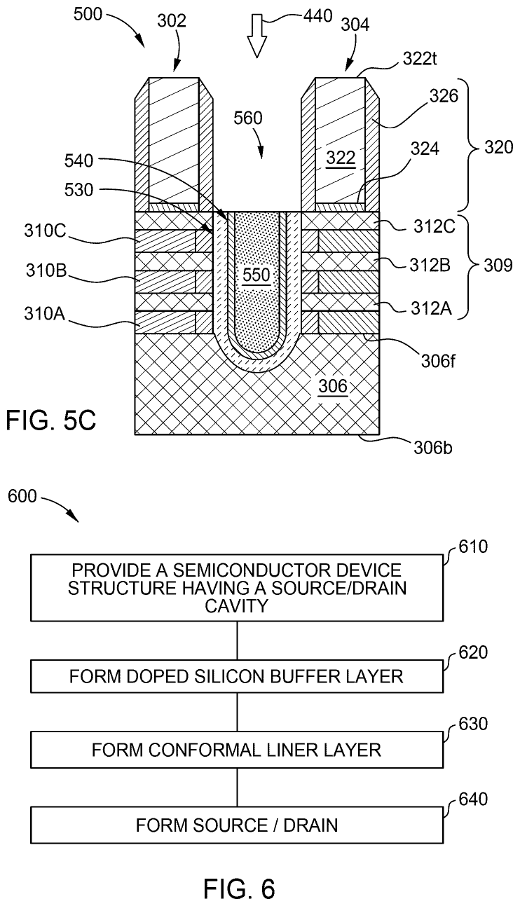

FIG. 4 illustrates an exemplary flow chart of a method 400 of forming a nano-FET structure in accordance with one or more embodiments of the present disclosure. FIGS. 5A-5C illustrate schematic views of various stages of forming a nano-FET structure in accordance with one or more embodiments of the present disclosure. With reference to FIGS. 5A-5C, schematic views of some embodiments of a nano-FET structure at various stages of manufacture are provided to illustrate the method of FIG. 4. Although FIGS. 5A-5C are described in relation to the method 200, it will be appreciated that the structures disclosed in FIGS. 5A-5C are not limited to the method 400, but instead may stand alone as structures independent of the method 400. Similarly, although the method 400 is described in relation to FIGS. 5A-5C, it will be appreciated that the method 400 is not limited to the structures disclosed in FIGS. 5A-5C, but instead may stand alone independent of the structures disclosed in FIGS. 5A-5C. The method 400 may be used to form portions of the nano-FET 100 depicted in FIG. 1.

At operation 410, a semiconductor device structure 500 having a source/drain cavity 308 is provided. The semiconductor device structure 500 may be or be part of a multi-gate device with three-dimensional architecture, such as fin based semiconductor devices including nano-FETs and gate-all-around (GAA) transistor devices. The semiconductor device structure 500 is similar to the semiconductor device structure 300. In some embodiments, the first inner spacers 332A-C are not present and sidewalls of the first semiconductor layers 310A-C define the source/drain cavity 308. A cleaning process may be performed to remove contamination, oxide, and debris present in the source/drain cavity 308 prior to operation 420.

Referring to FIG. 5A, at operation 420, a first liner layer of semiconductor material 530 is epitaxially grown. In one or more embodiments, the first liner layer of semiconductor material 530 is a conformal or substantially conformal layer. In one or more other embodiments, the first liner layer of semiconductor material 530 is nonconformal or substantially nonconformal. The first liner layer of semiconductor material 530 is formed on surfaces of the source/drain cavity 308, for example the sidewall surfaces 308s and the bottom surface 308b of the source/drain cavity 308. In some embodiments due to the presence of inner spacers 332A-C along the sidewall surfaces 308s, the first liner layer of semiconductor material 530 is highly defective. For example, the first liner layer of semiconductor material 530 may not grow properly on the dielectric surfaces of the inner spacers 332A-C leading to the formation of knuckles, which reduces the conformality of the first liner layer of semiconductor material 530. A thickness of the first liner layer of semiconductor material 530 can be equal to or greater than 50 angstroms (Å). In one or more embodiments, a material of the first liner layer of semiconductor material 530 is silicon germanium (Si₁₋ₓGeₓ, where x is in a range from about 10 to about 30 or in a range from about 10 to about 20). In some embodiments, if the semiconductor device structure 300 is a p-type structure, the first liner layer of semiconductor material 530 can include silicon germanium (SiGe) doped with a p-type dopant, such as boron or gallium.

In some embodiments, the process conditions for the epitaxial growth process of operation 420 are selected so that the first liner layer of semiconductor material 530 has a similar growth rate on the (100) surfaces, for example, the bottom surface 308b, relative to the (110) surfaces, for example, the sidewall surfaces 308s such that the first layer of semiconductor material 530. The first liner layer of semiconductor material 530 may be formed using process conditions similar to the liner layer of semiconductor material 350.

Referring to FIG. 5B, at operation 430, a doped silicon liner layer 540 is formed on the first liner layer of semiconductor material 530. The doped silicon liner layer 540 is a conformal or substantially conformal layer. The doped silicon liner layer 540 can be a boron doped silicon layer. Not to be bound by theory but it is believed that the doped silicon liner layer 540 prevents dislocations introduced by the first liner layer of semiconductor material 530 and the underlying material from affecting the source/drain feature 560. The doped silicon liner layer 540 can be formed using process conditions similar to the processing conditions used to form the doped silicon insertion layer 370.

In one or more embodiments, the doped silicon liner layer 540 is grown on the first liner layer of semiconductor material 530 as shown in FIG. 5A. In one or more embodiments, a material of the doped silicon liner layer 540 is silicon which is doped, such as by boron (e.g., boron-doped silicon (Si(B)). A concentration of a dopant in the doped silicon liner layer 540 can be in a range from about 1×10¹⁹ cm⁻³ to about 1×10²¹ cm⁻³. In one or more embodiments, the concentration of dopant in the doped silicon liner layer 540 is greater than the concentration of dopant in the fill layer of semiconductor material 550. The doped silicon liner layer 540 can be epitaxially grown using a silicon source precursor and dopant precursor, for example, a boron dopant precursor. The silicon source precursor can be or include silane (SiH₄), a higher order silane, halogenated silane, for example, dichlorosilane, organosilane, or a combination thereof as described herein. A dopant source can be flowed during the epitaxial growth the doped silicon liner layer 540 to in-situ dope the doped silicon liner layer 540. The dopant source can be or include a borane, organoborane (e.g., alkylboranes), and boron halide.

In one or more embodiments for forming the doped silicon liner layer 540, the silicon source precursor is dichlorosilane, the etchant gas is HCl, and the dopant source is diborane and optionally BCl3.

Referring to FIG. 5C, at operation 440, a fill layer of semiconductor material 550 is epitaxially grown in the source/drain cavity 308 to form the source/drain feature 560. The fill layer of semiconductor material 550 is grown in the source/drain cavity 308 defined by the doped silicon liner layer 540. In one or more embodiments, the fill layer of semiconductor material 550 fills the source/drain cavity 308 to complete the source/drain feature 560. In other embodiments, the fill layer of semiconductor material 550 partially fills the source/drain cavity 308 and is followed by deposition of one or more additional layers of semiconductor material to fill the source/drain cavity 308 and complete the source/drain feature 560. The fill layer of semiconductor material 550 is formed on the surface of the doped silicon liner layer 540. In some embodiments, the process conditions for the epitaxial growth process of operation 440 are selected so that the fill layer of semiconductor material 550 has an increased growth rate on the (100) surfaces relative to the (110) surfaces such that the epitaxial growth process of operation 440 is a substantially bottom-up or anisotropic growth process. The epitaxial deposition process of operation 440 may be performed similarly to the deposition process of operation 260.

In some embodiments, the source/drain feature 560 can further include additional layers, of semiconductor material. The various layers of semiconductor material can have varying concentrations of germanium. In one or more embodiments, where the source/drain feature 560 is formed using a deposition/purge process, during the purge process, gases remaining in the recess deposit a layer of semiconductor material that is compositionally different from a layer of semiconductor material deposited during the deposition process. For example, the second layer of semiconductor material 550 is deposited during a deposition process and has a higher concentration of germanium whereas a third layer of semiconductor material deposited during the purge process, which has a lower concentration of germanium, and a fourth layer of semiconductor material deposited during the deposition process has a higher concentration of germanium.

After deposition of the source/drain features 560, an anneal process may be performed to activate the source/drain features 560. In some embodiments, the anneal process may include a rapid thermal anneal (RTA) process, a laser spike anneal process, a flash anneal process, or a furnace anneal process. The anneal process may include a peak anneal temperature in a range from about 900 degrees Celsius and about 1000 degrees Celsius. In these embodiments, the peak anneal temperature may be maintained for a duration measured by seconds or microseconds. Through the anneal process, a targeted electronic contribution of the p-type dopant in the semiconductor host, such as silicon germanium (SiGe) or germanium (Ge), may be obtained. The anneal process may generate vacancies that facilitate movement of the p-type dopant from interstitial sites to substitutional lattice sites and reduce damage or defects in the lattice of the semiconductor host.

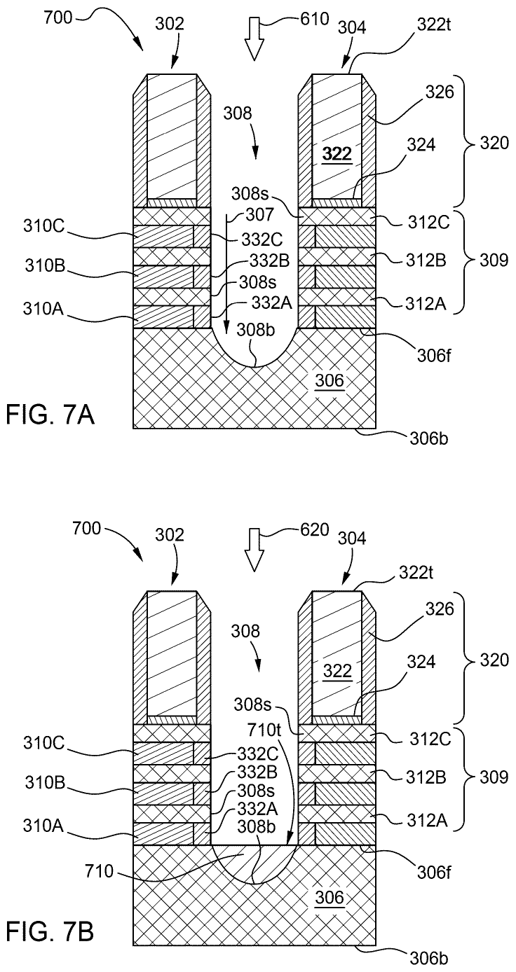

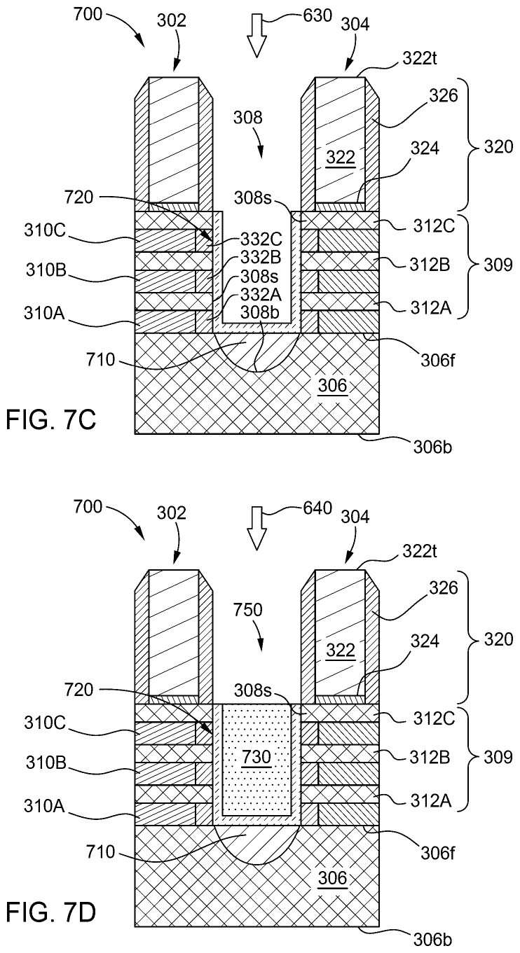

FIG. 6 illustrates an exemplary flow chart of a method 600 of forming a nano-FET structure in accordance with one or more embodiments of the present disclosure. FIGS. 7A-7C illustrate schematic views of various stages of forming a nano-FET structure in accordance with one or more embodiments of the present disclosure. With reference to FIGS. 7A-7C, schematic views of some embodiments of a nano-FET structure at various stages of manufacture are provided to illustrate the method of FIG. 6. Although FIGS. 7A-7C are described in relation to the method 600, it will be appreciated that the structures disclosed in FIGS. 7A-7C are not limited to the method 600, but instead may stand alone as structures independent of the method 600. Similarly, although the method 600 is described in relation to FIGS. 7A-7C, it will be appreciated that the method 600 is not limited to the structures disclosed in FIGS. 7A-7C, but instead may stand alone independent of the structures disclosed in FIGS. 7A-7C. The method 600 may be used to form portions of the nano-FET 100 depicted in FIG. 1.

Referring to FIG. 7A, at operation 610, a semiconductor device structure 700 having a source/drain cavity 308 is provided. The semiconductor device structure 700 may be or be part of a multi-gate device with three-dimensional architecture, such as fin based semiconductor devices including nano-FETs and gate-all-around (GAA) transistor devices. The semiconductor device structure 700 is similar to the semiconductor device structure 300. In some embodiments, the first inner spacers 332A-C are not present and sidewalls of the first semiconductor layers 310A-C define the source/drain cavity 308. The substrate 306 includes a recess 307, which extends from the frontside 306f into the substrate 306. A cleaning process may be performed to remove contamination, oxide, and debris present in the source/drain cavity 308 prior to operation 420.

Referring to FIG. 7B, at operation 620 a doped silicon buffer layer 710 is formed in the recess 307 of the substrate 306. In at least one embodiment, the doped silicon buffer layer 710 is a boron doped silicon layer. The doped silicon buffer layer 710 may be formed similarly to the doped silicon liner layer 540 or the doped silicon insertion layers 360a-d. Growth of doped silicon buffer layer 710 in the recess 307 enables the termination of dislocations from the substrate 306 to terminate at the doped silicon buffer layer 710. In addition, the doped silicon buffer layer 710 provides a flat or substantially flat surface, which enables epitaxial growth such that a single crystalline epitaxial layer is formed on the frontside 306f of the substrate 306. The recess 307 extends from the frontside 306f of the substrate 306 into the substrate 306. Thus, a top surface 710t of the doped silicon buffer layer 710 may be coplanar or substantially coplanar with the frontside 306f of the substrate 306.

Referring to FIG. 7C, at operation 630 a liner layer of semiconductor material 720 is epitaxially grown. In one or more embodiments, the liner layer of semiconductor material 720 is a conformal or substantially conformal layer. The liner layer of semiconductor material 720 is formed on surfaces of the source/drain cavity 308, for example the sidewall surfaces 308s of the source/drain cavity 308 and the top surface 710t of the doped silicon buffer layer 710. A thickness of the first liner layer of semiconductor material 530 can be equal to or greater than 50 angstroms (Å). In one or more embodiments, a material of the liner layer of semiconductor material 720 is silicon germanium (Si₁₋ₓGeₓ, where x is in a range from about 10 to about 30 or in a range from about 10 to about 20).

In some embodiments, the process conditions for the epitaxial growth process of operation 630 are selected so that the liner layer of semiconductor material 720 has a similar growth rate on the (100) surfaces, for example, the top surface 710t of the doped silicon buffer layer 710, relative to the (110) surfaces, for example, the sidewall surfaces 308s such that the liner layer of semiconductor material 720 is conformal or substantially conformal. The liner layer of semiconductor material 720 may be formed using process conditions similar to the liner layer of semiconductor material 350.

Referring to FIG. 7D, at operation 640, a fill layer of semiconductor material 730 is epitaxially grown in the source/drain cavity 308 to form the source/drain feature 750. The fill layer of semiconductor material 730 is grown in the source/drain cavity 308 defined by the liner layer of semiconductor material 720. In one or more embodiments, the fill layer of semiconductor material 730 fills the source/drain cavity 308 to complete the source/drain feature 750. In other embodiments, the fill layer of semiconductor material 730 partially fills the source/drain cavity 308 and is followed by deposition of one or more additional layers of semiconductor material to fill the source/drain cavity 308 and complete the source/drain feature 750. The fill layer of semiconductor material 730 is formed on the surface of the liner layer of semiconductor material 720. In some embodiments, the process conditions for the epitaxial growth process of operation 640 are selected so that the fill layer of semiconductor material 730 has an increased growth rate on the (100) surfaces relative to the (110) surfaces such that the epitaxial growth process of operation 640 is a substantially bottom-up or anisotropic growth process. The epitaxial deposition process of operation 640 may be performed similarly to the deposition process of operation 260.

In some embodiments, the source/drain feature 750 can further include additional layers, of semiconductor material. The various layers of semiconductor material can have varying concentrations of germanium. In one or more embodiments, where the source/drain feature 750 is formed using a deposition/purge process, during the purge process, gases remaining in the recess deposit a layer of semiconductor material that is compositionally different from a layer of semiconductor material deposited during the deposition process. For example, the fill layer of semiconductor material 730 is deposited during a deposition process and has a higher concentration of germanium whereas a third layer of semiconductor material deposited during the purge process, which has a lower concentration of germanium, and a fourth layer of semiconductor material deposited during the deposition process has a higher concentration of germanium.

After deposition of the source/drain features 750, an anneal process may be performed to activate the source/drain features 750. In some embodiments, the anneal process may include a rapid thermal anneal (RTA) process, a laser spike anneal process, a flash anneal process, or a furnace anneal process. The anneal process may include a peak anneal temperature in a range from about 900 degrees Celsius and about 1000 degrees Celsius. In these embodiments, the peak anneal temperature may be maintained for a duration measured by seconds or microseconds. Through the anneal process, a targeted electronic contribution of the p-type dopant in the semiconductor host, such as silicon germanium (SiGe) or germanium (Ge), may be obtained. The anneal process may generate vacancies that facilitate movement of the p-type dopant from interstitial sites to substitutional lattice sites and reduce damage or defects in the lattice of the semiconductor host.

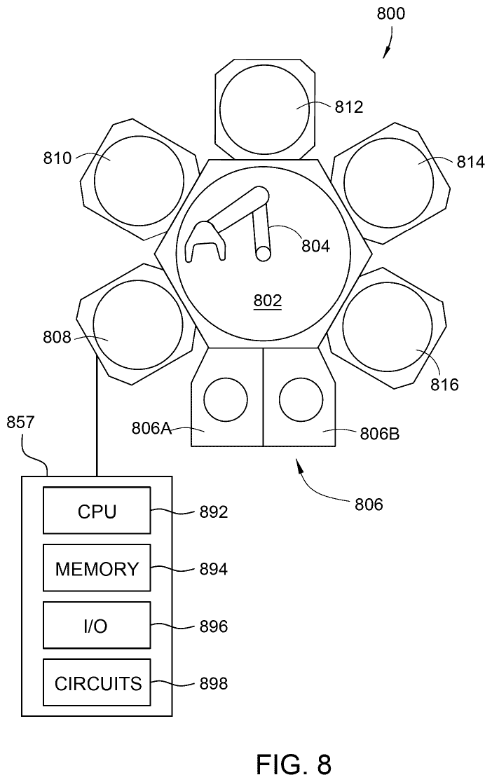

FIG. 8 illustrates a plan view of a cluster tool 800 in accordance with one or more embodiments of the present disclosure. The cluster tool 800 may be used to perform various operations of the method 200, the method 400, or the method 600. The cluster tool 800 features at least one material deposition chamber, for example, a plasma-enhanced chemical vapor deposition (PECVD) chamber and optionally an epitaxial deposition chamber. The epitaxial deposition chamber may be a plasma-enhanced epitaxial deposition chamber. One example of the cluster tool 800 is the CENTURA® EPI system available from Applied Materials, Inc., of Santa Clara, California. Cluster tools manufactured by others may be used as well. A transfer robot 804 of any convenient type is disposed in a transfer chamber 802 of the cluster tool 800. A load-lock 806, with two load-lock chambers 806A, 806B is coupled to the transfer chamber 802. A plurality of processing chambers 808, 810, 812, 814, and 816 are also coupled to the transfer chamber 802. In at least one aspect, the plurality of processing chambers 808, 810, 812, 814, and 816 includes at least one of a pre-clean chamber, a material deposition chamber such as an epitaxial deposition chamber, a plasma-enhanced chemical vapor deposition chamber, and a thermal processing chamber, such as an anneal, degas, or oxidation chamber.

Processing chamber 808 may be a pre-clean chamber configured to clean the substrate prior to material deposition of materials, for example, a sacrificial capping layer, a source/drain material, or a superlattice structure. The pre-clean chamber may be configured to perform the Applied Materials SICONI™ Pre-clean process. Processing chamber 810 and/or 814 may be a material deposition chamber such as an epitaxial deposition chamber capable of performing an epitaxial growth process or a plasma-enhanced chemical vapor deposition process. Processing chamber 812 and/or 816 may be an additional material deposition chamber or a thermal treatment chamber capable of performing a thermal treatment process.

Processes, for example, one or more of operations 210-260, one or more of operations 410-440, or one or more of operations 610-640, may generally be stored in the memory of the system controller 857 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, for example, an application specific integrated circuit or other type of hardware embodiment, or as a combination of software and hardware. The software routine, when executed by the processor, transforms the general-purpose computer into a specific purpose computer (controller) that controls the chamber operation such that the processes are performed.

In at least one embodiment, the system controller 857 has a configuration to control the epitaxial growth chamber to grow epitaxial materials, for example, one or more of the source/drain feature 380 and the source/drain feature 560.

The cluster tool 800 may be used to perform at least portions of the method 200, the method 400, or the method 600 described above. During processing, a substrate that is to be processed ma y arrive to the cluster tool 800 in a pod (not shown). The substrate is transferred from the pod to the vacuum compatible load-lock chambers 806A, 806B by the factory interface robot (not shown). The substrate is then picked by the transfer robot 804 in the transfer chamber 802, which is generally kept in a vacuum state. The transfer robot 804 then loads the substrate into the processing chamber 808 for cleaning. The transfer robot 804 then picks up the substrate from the processing chamber 808 and loads the substrate into the processing chamber 810 or 814, whichever is available, for epitaxial deposition. Epitaxial materials as described may be grown on the cleaned substrate in the processing chamber 810 or 814. The transfer robot 804 then picks up the substrate from the processing chamber 810 or 814 and transfers the substrate into the processing chamber 812 or 816, which are thermal processing chambers, whichever is available. The epitaxial materials may then be exposed to a rapid heating/cooling process. The transfer robot 804 then picks the substrate from the processing chamber 812 or 816 and transfers the substrate to processing chamber 814 for deposition of additional materials over the epitaxial materials.

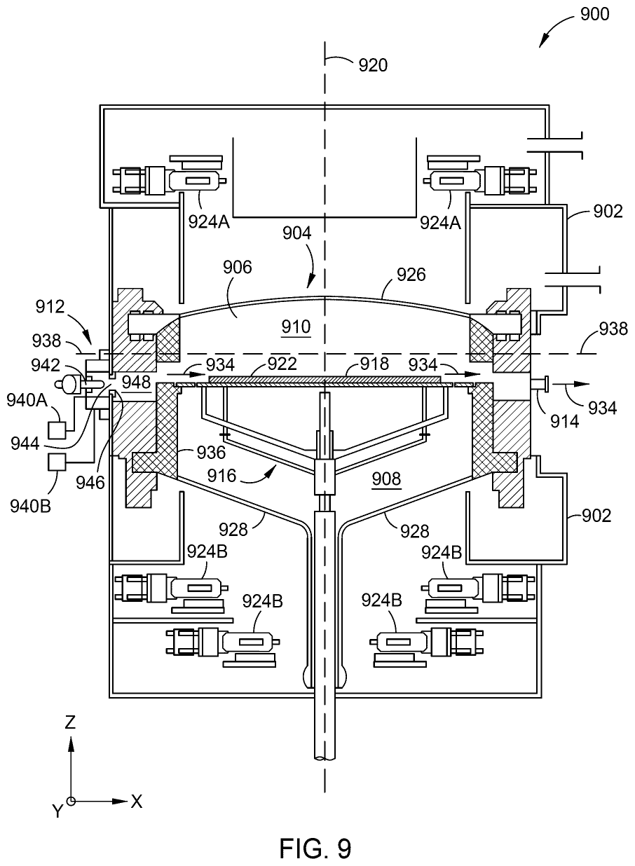

FIG. 9 illustrates a cross-sectional view of a processing chamber 900 in accordance with one or more embodiments of the present disclosure. The processing chamber 900 is adapted to perform an epitaxial (Epi) deposition process as detailed below. The processing chamber 900 may be the processing chamber 808, 810, 812, 814, or 816 shown in FIG. 8.

The processing chamber 900 includes a housing structure 902 made of a process resistant material, such as aluminum or stainless steel, for example 916 L stainless steel. The housing structure 902 encloses various functioning elements of the processing chamber 900, such as a quartz chamber 904, which includes an upper quartz chamber 906, and a lower quartz chamber 908, in which a processing volume 910 is contained. Reactive species are provided to the quartz chamber 904 by a gas distribution assembly 912, and processing byproducts are removed from the processing volume 910 by an outlet port 914, which is typically in communication with a vacuum source (not shown).

A substrate support 916 is adapted to receive a substrate 918 that is transferred to the processing volume 910. The substrate support 916 is disposed along a longitudinal axis 920 of the processing chamber 900. The substrate support 916 may be made of a ceramic material or a graphite material coated with a silicon material, such as silicon carbide, or other process resistant material. Reactive species from precursor reactant materials are applied to a surface 922 of the substrate 918, and byproducts may be subsequently removed from the surface 922 of the substrate 918. Heating of the substrate 918 and/or the processing volume 910 may be provided by radiation sources, such as upper lamp modules 924A and lower lamp modules 924B.

In one embodiment, the upper lamp modules 924A and the lower lamp modules 924B are infrared (IR) lamps. Non-thermal energy or radiation from the lamp modules 924A and 924B travels through an upper quartz window 926 of the upper quartz chamber 906, and through a lower quartz window 928 of the lower quartz chamber 908. Cooling gases for the upper quartz chamber 906, if needed, enter through an inlet and exit through an outlet. Precursor reactant materials, as well as diluent, purge and vent gases for the processing chamber 900, enter through the gas distribution assembly 912 and exit through the outlet port 914. While the upper quartz window 926 is shown as being curved or convex, the upper quartz window 926 may be planar or concave as the pressure on both sides of the upper quartz window 926 is substantially the same (i.e., atmospheric pressure).

The low wavelength radiation in the processing volume 910, which is used to energize reactive species and assist in adsorption of reactants and desorption of process byproducts from the surface 922 of the substrate 918, typically ranges from about 0.8 μm to about 1.2 μm, for example, between about 0.95 μm to about 1.05 μm, with combinations of various wavelengths being provided, depending, for example, on the composition of the film which is being epitaxially grown.

The component gases enter the processing volume 910 via the gas distribution assembly 912. Gas flows from the gas distribution assembly 912 and exits through the outlet port 914 as shown generally by a flow path 934. Combinations of component gases, which are used to clean/passivate a substrate surface, or to form the silicon and/or germanium-containing film that is being epitaxially grown, are typically mixed prior to entry into the processing volume 910. The overall pressure in the processing volume 910 may be adjusted by a valve (not shown) on the outlet port 914. At least a portion of the interior surface of the processing volume 910 is covered by a liner 936. In one embodiment, the liner 936 comprises a quartz material that is opaque. In this manner, the chamber wall is insulated from the heat in the processing volume 910.

The temperature of surfaces in the processing volume 910 may be controlled within a temperature range of about 200 °C to about 600 °C, or greater, by the flow of a cooling gas, which enters through an inlet and exits through an outlet, in combination with radiation from the upper lamp modules 924A positioned above the upper quartz window 926. The temperature in the lower quartz chamber 908 may be controlled within a temperature range of about 200 °C to about 600 °C or greater, by adjusting the speed of a blower unit which is not shown, and by radiation from the lower lamp modules 924B disposed below the lower quartz chamber 908. The pressure in the processing volume 910 may be between about 0.1 Torr to about 600 Torr, such as between about 5 Torr to about 70 Torr.

The temperature on the surface 922 of the substrate 918 may be controlled by power adjustment to the lower lamp modules 924B in the lower quartz chamber 908, or by power adjustment to both the upper lamp modules 924A overlying the upper quartz window 926, and the lower lamp modules 924B in the lower quartz chamber 908. The power density in the processing volume 910 may be between about 40 W/cm² to about 400 W/cm², such as about 80 W/cm² to about 120 W/cm².

In one aspect, the gas distribution assembly 912 is disposed normal to, or in a radial direction 938 relative to, the longitudinal axis 920 of the processing chamber 900 or the substrate 918. In this orientation, the gas distribution assembly 912 is adapted to flow process gases in the radial direction 938 across, or parallel to, the surface 922 of the substrate 918. In one processing application, the process gases are preheated at the point of introduction to the processing chamber 900 to initiate preheating of the gases prior to introduction to the processing volume 910, and/or to break specific bonds in the gases. In this manner, surface reaction kinetics may be modified independently from the thermal temperature of the substrate 918.

In operation, precursors used to form silicon (Si) and silicon germanium (SiGe) blanket or selective epitaxial films are provided to the gas distribution assembly 912 from one or more gas sources 940A and 940B. IR lamps 942 (only one is shown in FIG. 9) may be utilized to heat the precursors within the gas distribution assembly 912 as well as along the flow path 934. The gas sources 940A, 940B may be coupled the gas distribution assembly 912 in a manner adapted to facilitate introduction zones within the gas distribution assembly 912, such as a radial outer zone and a radial inner zone between the outer zones when viewed in from a top plan view. The gas sources 940A, 940B may include valves (not shown) to control the rate of introduction into the zones.

The gas sources 940A, 940B may include silicon precursors such as silanes, including silane (SiH₄), disilane (Si₂H₆,), dichlorosilane (SiH₂Cl₂), hexachlorodisilane (Si₂Cl₆), dibromosilane (SiH₂Br₂), higher order silanes, derivatives thereof, and combinations thereof. The gas sources 940A, 940B may also include germanium containing precursors, such as germane (GeH₄), digermane (Ge₂H₆), germanium tetrachloride (GeCl₄), dichlorogermane (GeH₂Cl₂), derivatives thereof, and combinations thereof. The silicon and/or germanium containing precursors may be used in combination with hydrogen chloride (HCl), chlorine gas (Cl₂), hydrogen bromide (HBr), and combinations thereof. The gas sources 940A, 940B may include one or more of the silicon and germanium containing precursors in one or both of the gas sources 940A, 940B.

The precursor materials enter the processing volume 910 through openings or holes 944 (only one is shown in FIG. 9) in the perforated plate 946 in this excited state, which in one embodiment is a quartz material, having the holes 944 formed therethrough. The perforated plate 946 is transparent to IR energy, and may be made of a clear quartz material. In other embodiments, the perforated plate 946 may be any material that is transparent to IR energy and is resistant to process chemistry and other processing chemistries. The energized precursor materials flow toward the processing volume 910 through the holes 944 in the perforated plate 946, and through channels 948 (only one is shown in FIG. 9). A portion of the photons and non-thermal energy from the IR lamps 942 also passes through the holes 944, the perforated plate 946, and channels 948 facilitated by a reflective material and/or surface disposed on the interior surfaces of the gas distribution assembly 912, thus illuminating the flow path 934 of the precursor materials. In this manner, the vibrational energy of the precursor materials may be maintained from the point of introduction to the processing volume 910 along the flow path.

The previously described embodiments of the present disclosure have many advantages. The Doped Silicon layer (p type or n-type depending on the application) provides a means to initiate a defect free interface of the active device in the recess. The doped silicon layer is lattice matched to the substrate and thus does not contribute to the strain in the film causing no defects. The doped silicon layer is used as a buffer, providing a single plane starting surface for the subsequent fill. The doped silicon layer also help in providing a contamination free starting surface. Highly B-Doped Silicon layer is tensile strained as opposed to the compressively strained SiGe/SiGeB. When B-doped Si is added in the SiGe/SiGeB layer as insertion layers, the strain field is modified due to the change of the sign of the strain from compressive to tensile. With this insertion layer, the threading dislocation tends to bend over going from one strain field to another. Alternating the strain field is a method to confine the dislocation to the bottom of the recess. The number of the insertion layers and thickness is dependent on the severity of dislocation nucleation. This is determined by the Ge% in the recess fill and the recess depth to be filled. Highly doped Si layers used as dislocation filters for compressively strained SiGe/SiGeB to limit the dislocation at the bottom of the recess and provide a high-quality strained recess fill near the active regions of the device such as Si channel. However, the present disclosure does not necessitate that all the advantageous features and all the advantages need to be incorporated into every embodiment of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, embodiment, embodiment, or example of the present disclosure, or a particular claim, that feature can also be used, to the extent possible in combination with and/or in the context of other particular aspects and embodiments of the present disclosure, and in the present disclosure generally.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A method of forming a semiconductor device, comprising:
epitaxially growing a liner layer of semiconductor material on a pair of opposing sidewall surfaces and a bottom surface, the pair of opposing sidewall surfaces and the bottom surface defining a source/drain cavity;
epitaxially growing a fill layer of semiconductor material on the liner layer of semiconductor material in the source/drain cavity by a bottom-up growth process, the fill layer of semiconductor material partially filing the source/drain cavity;
epitaxially growing a doped silicon insertion layer on the fill layer of semiconductor material; and
repeating epitaxially growing the fill layer and epitaxially growing the doped silicon insertion layer to achieve a targeted thickness.

2. The method of claim 1, wherein the doped silicon insertion layer comprises silicon doped with boron.

3. The method of claim 2, wherein the liner layer comprises silicon germanium doped with a p-type dopant, the liner layer having a first germanium concentration and a first dopant concentration.

4. The method of claim 3, wherein the fill layer comprises silicon germanium doped with the p-type dopant, the fill layer having a second germanium concentration, which is greater than the first germanium concentration and a second dopant concentration, which is greater than the first dopant concentration.

5. The method of claim 1, wherein epitaxially growing the liner layer is performed at a first temperature in a range from about 700 degrees Celsius to about 750 degrees Celsius.

6. The method of claim 5, wherein epitaxially growing the fill layer is performed at a second temperature in a range from about 500 degrees Celsius to about 700 degrees Celsius and the second temperature is less than the first temperature.

7. The method of claim 1, wherein epitaxially growing the liner layer is performed at a first pressure in a range from about 10 Torr to about 200 Torr.

8. The method of claim 7, wherein epitaxially growing the fill layer is performed at a second pressure in a range from about 5 Torr to about 20 Torr and the second pressure is less than the first pressure.

9. A method of forming a semiconductor device, comprising:
epitaxially growing a first liner layer of semiconductor material on a pair of opposing sidewall surfaces and a bottom surface, the pair of opposing sidewall surfaces and the bottom surface defining a source/drain cavity;
epitaxially growing a second liner layer of semiconductor material on the first liner layer of semiconductor material, the second liner layer of semiconductor material comprises doped silicon; and
epitaxially growing a fill layer of semiconductor material on the second liner layer of semiconductor material in the source/drain cavity by a bottom-up growth process.

10. The method of claim 9, wherein the second liner layer of semiconductor material comprises silicon doped with boron.

11. The method of claim 10, wherein the first liner layer comprises silicon germanium doped with a p-type dopant, the first liner layer having a first germanium concentration and a first dopant concentration.

12. The method of claim 11, wherein the fill layer comprises silicon germanium doped with the p-type dopant, the fill layer having a second germanium concentration, which is greater than the first germanium concentration and a second dopant concentration, which is greater than the first dopant concentration.

13. The method of claim 9, wherein epitaxially growing the first liner layer is performed at a first temperature in a range from about 700 degrees Celsius to about 750 degrees Celsius.

14. The method of claim 13, wherein epitaxially growing the fill layer is performed at a second temperature in a range from about 500 degrees Celsius to about 700 degrees Celsius and the second temperature is less than the first temperature.

15. The method of claim 9, wherein epitaxially growing the first liner layer is performed at a first pressure in a range from about 10 Torr to about 200 Torr.

16. The method of claim 15, wherein epitaxially growing the fill layer is performed at a second pressure in a range from about 5 Torr to about 20 Torr and the second pressure is less than the first pressure.

17. A method of forming a semiconductor device, comprising:
epitaxially growing a buffer layer of semiconductor material on a bottom surface, the bottom surface and a pair of opposing sidewall surfaces defining a source/drain cavity, the bottom surface further defining a recess formed in a silicon-containing substrate, the buffer layer filling the recess;
epitaxially growing a liner layer of semiconductor material on the pair of opposing sidewall surfaces and a top surface of the buffer layer; and
epitaxially growing a fill layer of semiconductor material on the liner layer of semiconductor material in the source/drain cavity by a bottom-up growth process.

18. The method of claim 17, wherein the buffer layer comprises silicon doped with boron.

19. The method of claim 18, wherein the liner layer comprises silicon germanium doped with a p-type dopant, the liner layer having a first germanium concentration and a first dopant concentration.

20. The method of claim 19 wherein the fill layer comprises silicon germanium doped with the p-type dopant, the fill layer having a second germanium concentration, which is greater than the first germanium concentration and a second dopant concentration, which is greater than the first dopant concentration.
